(19) United States
(12) Patent Application Publication
(10) Pub. No.: US 2012/0097918 A1
(43) Pub. Date: Apr. 26, 2012

(54) IMPLANTED CURRENT CONFINEMENT STRUCTURE TO IMPROVE CURRENT SPREADING

(75) Inventors: San YU, Perrysburg, OH (US); Chi-Chun Chen, Gloucester, MA (US)

(73) Assignee: VARIAN SEMICONDUCTOR EQUIPMENT ASSOCIATES, INC., Gloucester, MA (US)

(21) Appl. No.: 13/276,790

(22) Filed: Oct. 19, 2011

Related U.S. Application Data
(60) Provisional application No. 61/394,806, filed on Oct. 20, 2010.

(51) Int. Cl. H01L 33/06; H01L 21/20

(52) U.S. Cl. 257/13; 438/478; 438/478; 257/E21.09; 257/E33.008

(57) ABSTRACT

Ion implantation is used to form a current confinement structure, such as that in a light emitting diode. This current confinement structure defines multiple cells in one embodiment, each of which may surround an undoped region. The ion implantation may be performed between formation of the various layers. In one embodiment, the formation of one layer is interrupted and then resumed after ion implantation is performed.

### CROSS-REFERENCE TO RELATED APPLICATIONS

This claims priority to the provisional patent application entitled “Implanted Current Confinement Structure to Improve Current Spreading in Light Emitting Diodes,” filed Oct. 20, 2010 and assigned U.S. App. No. 61/394,806, the disclosure of which is hereby incorporated by reference.

### FIELD

This invention relates to fabrication of current confinement structures and, more particularly, to ion implantation of light emitting diodes (LEDs) to form current confinement structures.

### BACKGROUND

Ion implantation is a standard technique for introducing conductivity-altering impurities into a workpiece. A desired impurity material is ionized in an ion source, the ions are accelerated to form an ion beam of prescribed energy, and the ion beam is directed at the surface of the workpiece. The energetic ions in the beam penetrate into the bulk of the workpiece material and are embedded into the crystalline lattice of the workpiece material to form a region of desired conductivity.

LEDs typically are built on a substrate and are doped with impurities to create a p-n junction. A current flows from the anode to the cathode, but not in the reverse direction. Electrons and holes flow into the p-n junction from electrodes with different voltages. If an electron meets a hole, it falls into a lower energy level and releases energy in the form of a photon. The wavelength of the light emitted by the LED and the color of the light may depend on the band gap energy of the materials forming the p-n junction.

FIG. 1 is a cross-sectional view of an LED. The LED 200 has a p-type layer 101, multiple quantum well (MQW) 108, and an n-type layer 102. In this embodiment, current 201 flows from the n electrode 104 to the p electrode 109. Current crowding occurs near the n electrode 104. Rather than spreading within or across the n-type layer 102, the current is retained near the n electrode 104. Current spreading and current crowding may affect efficiency of vertical or lateral LEDs. Current crowding, such as under a contact to an LED or in one region of an LED, will reduce the efficiency of the LED. Encouraging current spreading increases the brightness of the LED because, for example, any current concentration or light generation under the electrodes is reduced or eliminated. Accordingly, there is a need in the art for an improved current confinement structure and methods of LED ion implantation that improve current spreading and current crowding.

### SUMMARY

According to a first aspect of the invention, a method of forming a workpiece is provided. The method comprises forming a first portion of a first layer. A first patterned implant of the first layer with a species is performed. This first patterned implant forms a current confinement structure in the first layer. The current confinement structure defines a plurality of cells, each surrounding an undoped region. A second layer is formed on the first layer. This second layer has an opposite conductivity from the first layer.

According to a second aspect of the invention, an LED is provided. The LED comprises a first layer of material having a first conductivity. A second layer of the material has a second conductivity opposite of the first conductivity. An MQW is disposed between the first layer and the second layer. A current confinement structure is disposed in the first layer. This current confinement structure defines a plurality of cells and each of the plurality of cells surrounds an undoped region.

According to a third aspect of the invention, an LED is provided. The LED comprises a p-type GaN layer and an n-type GaN layer that defines a first surface and an opposite second surface. An MQW is disposed on the first surface of the n-type GaN layer and between the n-type GaN layer and the p-type GaN layer. A current confinement structure is disposed a distance beneath the first surface of the n-type GaN layer. This current confinement structure defines a plurality of polygons and each of the plurality of is polygons surrounds an undoped region.

### BRIEF DESCRIPTION OF THE DRAWINGS

For a better understanding of the present disclosure, reference is made to the accompanying drawings, which are incorporated herein by reference and in which:

FIG. 1 is a cross-sectional view of an LED;

FIG. 2 is a cross-sectional view of a current confinement structure for an LED;

FIGS. 3A-H are perspective views of current confinement structures;

FIGS. 4A-D are cross-sectional views of a first embodiment of a manufacturing process incorporating the current confinement structure of FIG. 2;

FIGS. 5A-D are cross-sectional views of a second embodiment of a manufacturing process incorporating the current confinement structure of FIG. 2;

FIGS. 6A-D are cross-sectional views of a third embodiment of a manufacturing process incorporating the current confinement structure of FIG. 2;

FIGS. 7A-D are cross-sectional views of a fourth embodiment of a manufacturing process incorporating the current confinement structure of FIG. 2;

FIG. 8 is a cross-sectional view of a current confinement structure in an n-type GaN layer;

FIG. 9 is a perspective view of a second embodiment of a current confinement structure;

FIG. 10 is a top perspective view of a third embodiment of a current confinement structure;

FIG. 11 is a top perspective view of a fourth embodiment of a current confinement structure; and

FIGS. 12A-B are perspective views of an embodiment forming a current confinement structure.

### DETAILED DESCRIPTION

The embodiments are described herein in connection with ion implantation of LEDs, but these embodiments also may be used with other semiconductor or workpiece manufacturing processes. A beam-line ion implanter, an implanter with a focused ion beam, a plasma doping ion implanter, an ion implanter that modifies a plasma sheath, or other ion implantation system known to those skilled in the art may be used in the embodiments described herein. Furthermore, the embodiments described herein may apply to many different LED architectures known to those skilled in the art, including lateral or vertical LED arrays different from those disclosed or illustrated. Thus, the invention is not limited to the specific embodiments described below.

FIG. 2 is a cross-sectional view of a current confinement structure for an LED. The LED 100 has a p-type layer 101, MQW 108, and an n-type layer 102. The p-type layer 101 and n-type layer 102 may be, for example, GaN, AlGaInP, other III/V compound semiconductors, or other II/VI compound semiconductors. The MQW 108 may be, for example, GaInN or AlGaInP. While specific dimensions of the n electrode 104 and p electrode 109 are illustrated, other dimensions are possible. The surface of the n-type layer 102 opposite of the MQW 108 may be disposed on a substrate in one embodiment. This substrate may be, for example, sapphire, silicon carbide, aluminum nitride, GaN, or silicon.

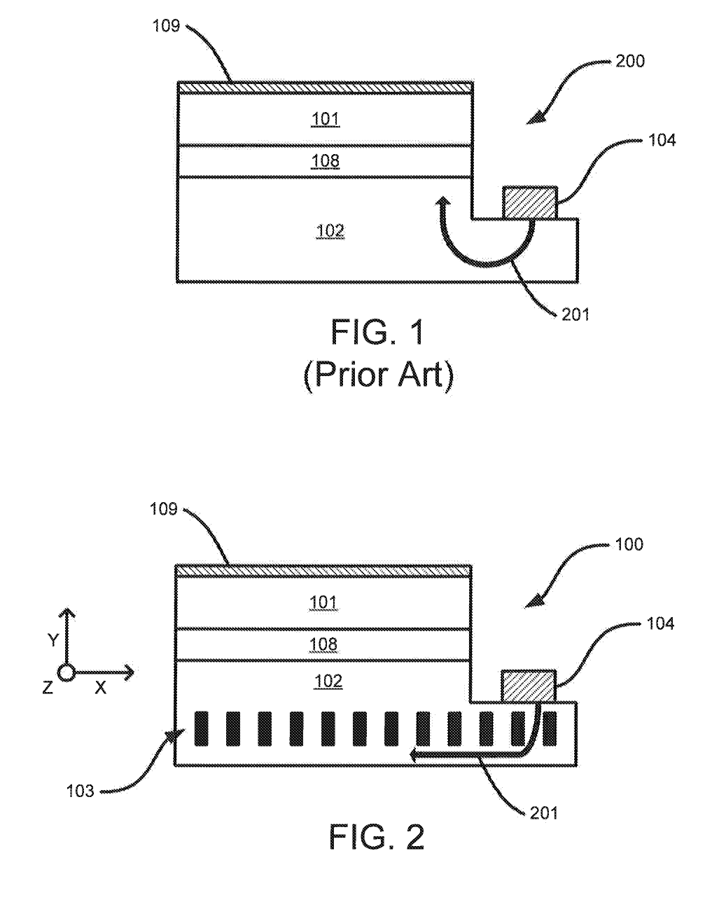

In this embodiment, current 201 flows from the n electrode 104 to the p electrode 109. The n-type layer 102 has a current confinement structure 103 (represented in FIG. 2 by the black boxes). The vertical walls of the current confinement structure 103 within the n-type layer 102 force current 201 from the n electrode 104 downward into the n-type layer 102. The current 201 is then spread throughout the n-type layer 102 (in the x-z plane) instead of crowding into the corner closest to the n electrode 104 as illustrated in FIG. 1.

Spreading the current 201 throughout the n-type layer 102 as illustrated in FIG. 2 has multiple benefits. First, the uniformly distributed current over an effective LED emission area may improve the brightness uniformity. Second, the current spreading structure could eliminate the local concentration of current to improve the efficiency droop and, as a result, it could significantly improve the overall device efficiency of the LED 100. Third, the current spreading structure could eliminate current crowding into the corner and improve electrostatic discharge (ESD) effect, which also may improve reliability. Fourth, the defect density of the GaN growth on top of the current confinement structure 103 may be improved due to the epitaxial lateral overgrowth (ELOG) effect of defect density reduction. In one specific example, light output of the LEI) 100 was increased over 1.0% compared to an LED without a current confinement structure 103. In the embodiment of FIG. 2, the current confinement structure 103 is implanted. For example, H, N, He, Ar, O, Cr, Fe, Ne, F, Ti, C, Mg, B, or other atomic or molecular species may be implanted into the n-type layer 102 to change the resistivity. Resistivity may be changed due to deep levels introduced or by damage created in the n-type GaN layer 103. The implants or the damage caused by implantation may introduce deep levels inside the GaN band gap in the form of electron traps that form a current confinement structure 103 with high electrical resistivity. The implantation dose may be as low as approximately 1E11 cm⁻² or as high as approximately 5E17 cm⁻² depending on the design of the LED 100. The implantation energy may be selected to achieve the most effective current spreading. For example, the implantation energy may be between approximately 1 keV to 10 MeV depending on the structure of the LED 100. Higher implantation energy will result in a deeper depth of the current confinement structure 103. In one specific embodiment, N is implanted to form the current confinement layer 103 using an implantation energy of approximately 30 keV and a dose of approximately 5E15 cm⁻². In another specific embodiment, N is implanted to form the current confinement layer 103 using an implantation energy of 120 keV and a dose of 1E15 cm⁻².

Current spreading is improved and current crowding may be reduced through formation of the current confinement structure 103. The current confinement structure 103 may have a height or line width between approximately 10 nm and 10 μm depending on the design of the LED 100. The pitch of the current confinement structure 103 may be between approximately 10 nm and 100 μm depending on the size of the n electrode 104 or the size of the LED 100. The current confinement structure 103 may be implanted to between approximately 0 μm and 10 μm into the n-type layer 102 to affect current spreading. Of course, other dimensions are possible.

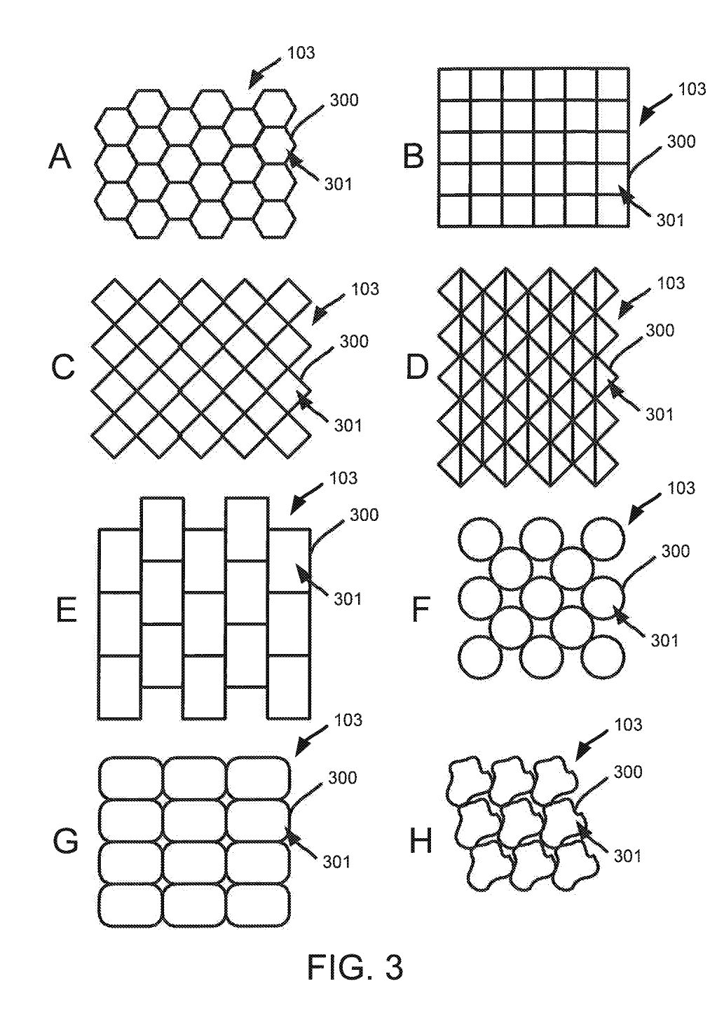

FIGS. 3A-H are perspective views of current confinement structures. The current confinement structure 103 may have one or multiple different patterns across all or part of a layer of the LED. These patterns in FIG. 3 are illustrated along the x-z plane as seen in FIG. 2 (i.e., looking in the y direction). For example, the current confinement structure 103 may be hexagonal (FIG. 3A), other polygonal shapes, square (FIG. 3B), diamonds (FIG. 3C), triangular (FIG. 3D), rectangular (FIG. 3E), circular (FIG. 3F), rounded (FIG. 30), oval, or other shapes (such as FIG. 3H). Each embodiment of the current confinement layer 103 illustrated in FIG. 3 has multiple cells 300. The current confinement structure 103 of each cell 300 surrounds an undoped region 301. Of course, the current confinement structure 103 also may be mesh-like, streak-like, blocks, or other shapes known to those skilled in the art that block or impede current flow. In one particular embodiment, the cells 300 in the current confinement structure 103 may have two or more different shapes. There also may be an undoped region between the various cells 300 as well as within the cells 300. This additional undoped region may be surrounded by the cells 300. In an alternate embodiment, the regions between the various cells 300 are completely doped, only leaving the undoped regions 301. In yet another embodiment, the interior regions of the cells 300 are doped and the undoped regions are disposed between the various cells 300. The cells 300 may be spaced apart in this embodiment or may surround any undoped region depending on the arrangement of the cells 300.

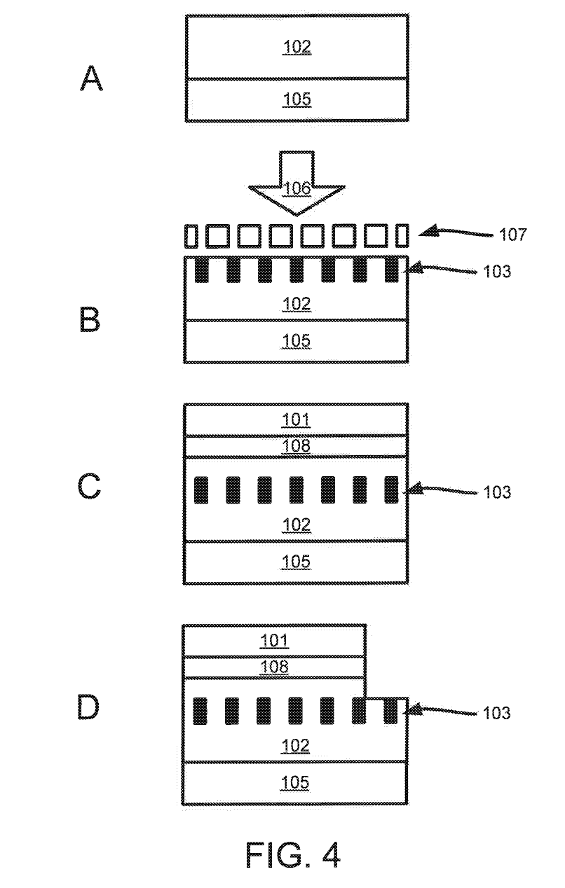

FIGS. 4A-D are cross-sectional views of a first embodiment of a manufacturing process incorporating the current confinement structure of FIG. 2. In FIG. 4A, the n-type layer 102 is grown on a substrate 105. The n-type layer 102 may be grown using metal organic chemical vapor deposition (MOCVD) in one instance.

MOCVD growth of the n-type layer 102 is interrupted after a first portion of the n-type layer 102 is formed and the current confinement structure 103 is implanted into the n-type layer 102 in FIG. 4B. In the embodiment of FIG. 4B, a species 106 is implanted through at least one mask 107 with apertures that correspond to the desired current confinement structure 103 that is to be implanted. While a mask 107 disposed above the n-type layer 102 is illustrated in FIG. 4B, the mask 107 may be disposed on the n-type layer 102.

In FIG. 4C, MOCVD growth is resumed and a second portion of the n-type layer 102 is formed. Thus, the current confinement structure 103 is below the surface of the n-type layer 102 in this embodiment. The MQW 108 and p-type layer 101 are then formed through MOCVD on the n-type layer 102. Then in FIG. 4D, a mesa etch is performed. Other processes, such as adding contacts, also are performed to finish the LEI).

As previously stated, the defect density of the GaN growth on top of the current confinement structure 103 may be improved due to the ELOG effect of defect density reduction. For example, a hexagon-shaped current confinement structure 103 may match later GaN growth in the n-type layer 102. GaN growth also may benefit from other shapes of the current confinement layer 103, such as circles, squares, diamonds, or polygons. In ELOG, part of the GaN is implanted and serves as a sort of mask. The GaN will not grow or grows less quickly on the implanted areas, so growth preferentially occurs in the unmasked, unimplanted areas. These cause the GaN to both grow vertically and laterally over the implanted areas. Any dislocations in the GaN near the edge of the unimplanted areas follow the lateral growth rather than the vertical growth.

In one particular embodiment, an oxide or nitride layer, which may have a thickness of approximately 100 A to 1000 A, is used as cap layer during implantation and is removed after implantation to continue MOCVD growth.

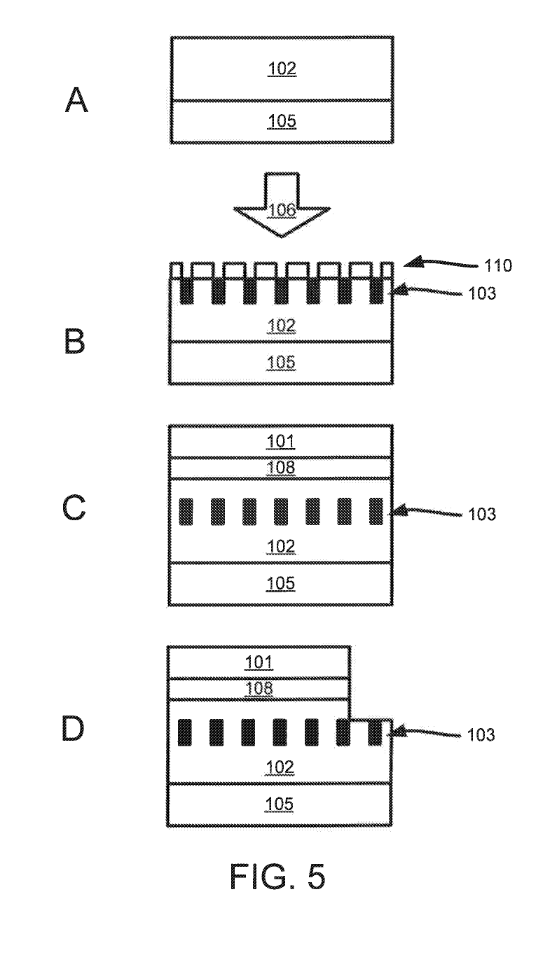

FIGS. 5A-D are cross-sectional views of a second embodiment of a manufacturing process incorporating the current confinement structure of FIG. 2. In FIG. 5A, the n-type layer 102 is grown on a substrate 105. The n-type layer 102 may be grown using MOCVD in one instance.

MOCVD growth of the n-type layer 102 is interrupted after a first portion of the n-type layer 102 is formed and the current confinement structure 103 is implanted into the n-type layer 102 in FIG. 4B. In the embodiment of FIG. 5B, a species 106 is implanted through at least one hard mask 110 with apertures that correspond to the desired current confinement structure 103 that is to be implanted. The hard mask 110 may be, for example, photoresist, an oxide, a nitride, or other materials on the n-type layer 102. The hard mask 110 may be patterned using lithography or other methods.

In FIG. 5C, the hard mask 110 is removed and MOCVD growth is resumed and a second portion of the n-type layer 102 is formed. Thus, the current confinement structure 103 is below the surface of the n-type layer 102 in this embodiment. The MQW 108 and p-type layer 101 are then formed through MOCVD on the n-type layer 102. Then in FIG. 5D, a mesa etch is performed. Other processes, such as adding contacts, also are performed to finish the LED.

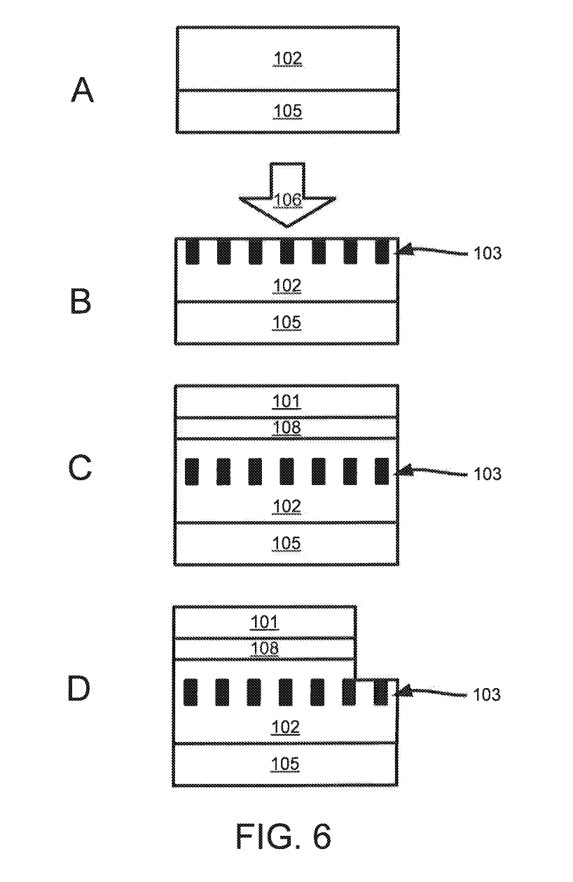

FIGS. 6A-D are cross-sectional views of a third embodiment of a manufacturing process incorporating the current confinement structure of FIG. 2. In FIG. 6A, the n-type layer 102 is grown on a substrate 105. The n-type layer 102 may be grown using MOCVD in one instance.

MOCVD growth of the n-type layer 102 is interrupted after a first portion of the n-type layer 102 is formed and the current confinement structure 103 is implanted into the n-type layer 102 in FIG. 6B. In the embodiment of FIG. 6B, a species 106 is implanted to form a pattern without a mask. This may be accomplished by varying a scan speed or scan pattern of the LED, a scan speed or scan pattern of the species 106, an implantation dose of the species 106, or a combination thereof. A beam-line ion implanter or an ion implanter that modifies a plasma sheath may be used to perform the implant illustrated in FIG. 6B. In one instance, the entire surface of the n-type layer 102 is implanted with at least a small dose but the dose or energy is varied to form the current confinement structure 103. Multiple implants may be needed in another instance. In one embodiment, the LED is rotated, such as 90°, and then another implant process is performed with the species 106.

In FIG. 6C, MOCVD growth is resumed and a second portion of the n-type layer 102 is formed. Thus, the current confinement structure 103 is below the surface of the n-type layer 102 in this embodiment. The MQW 108 and p-type layer 101 are then formed through MOCVD on the n-type layer 102. Then in FIG. 6D, a mesa etch is performed. Other processes, such as adding contacts, also are performed to finish the LED.

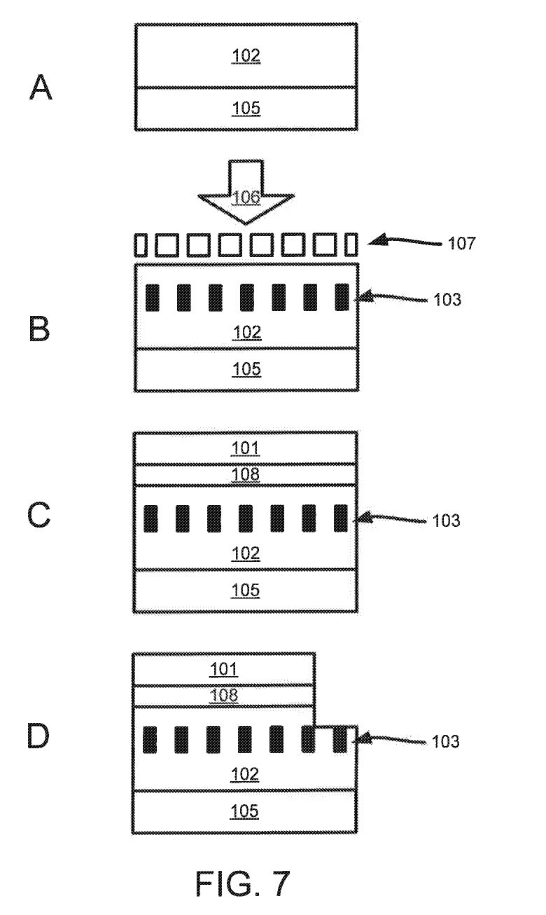

FIGS. 7A-D are cross-sectional views of a fourth embodiment of a manufacturing process incorporating the current confinement structure of FIG. 2. In FIG. 7A, the n-type layer 102 is grown on a substrate 105. The n-type layer 102 may be grown using MOCVD in one instance.

After MOCVD growth, the current confinement structure 103 is implanted into the n-type layer 102 in FIG. 7B. In the embodiment of FIG. 7B, a species 106 is implanted through at least one mask 107 with apertures that correspond to the desired current confinement structure 103 that is to be implanted. While a mask 107 disposed above the n-type layer 102 is illustrated in FIG. 7B, the mask 107 may be disposed on the n-type layer 102 or some other method may be used to perform the patterned implant. The implantation energy in the embodiment of FIG. 7 is larger than the implantation energy in the embodiments of for example, FIGS. 4-6. This is because the species 106 needs to penetrate to a deeper depth. The MQW 108 and p-type layer 101 are then formed through MOCVD on the n-type layer 102. Then in FIG. 7D, a mesa etch is performed. Other processes, such as adding contacts, also are performed to finish the LED.

While specific implant methods are disclosed in the embodiments of FIGS. 4-7, other masking methods also may be used to implant the current confinement structure 103. Two or more implants may be used in some embodiments. Two or more masks, such as mask 107, with different apertures may be used sequentially or simultaneously to form the desired pattern.

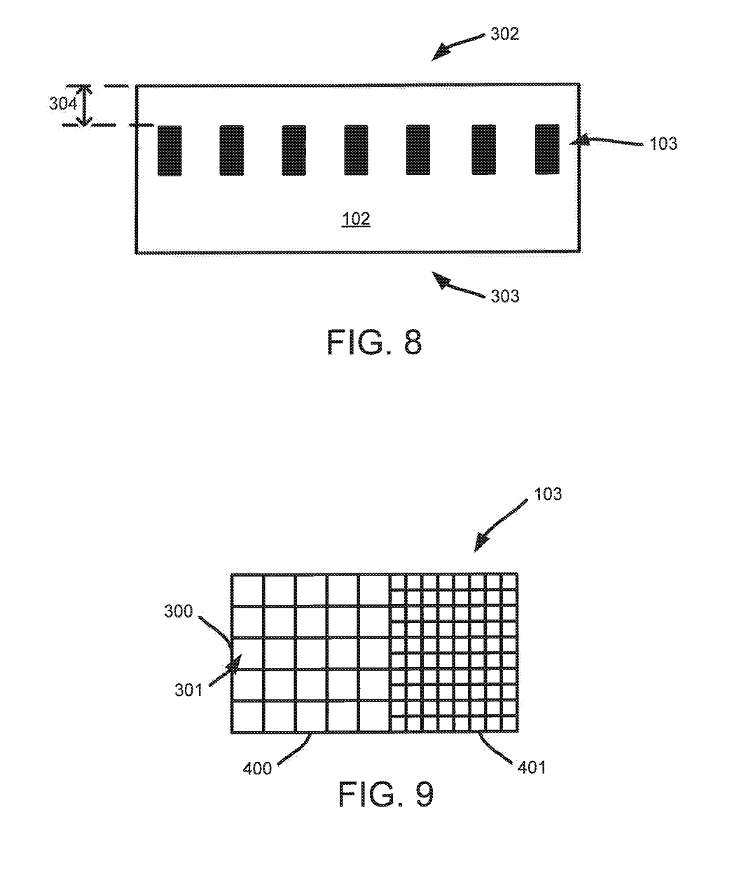

FIG. 8 is a cross-sectional view of a current confinement structure in an n-type GaN layer. The n-type layer 102 defines a first surface 302 and a second surface 303. The first surface 302 of the n-type layer 102 in FIG. 8 may be disposed on the MQW, such as the MQW 108 of FIG. 2. Turning back to FIG. 8, the current confinement structure 103 is disposed a distance 304 from the first surface 302 between the first surface 302 and second surface 303. The distance 304 may vary based on factors such as the LED architecture and manufacturing concerns. If MOCVD growth of the n-type layer 102 is interrupted for implantation, then the distance 304 may correspond to the second portion of the n-type layer 102 grown after implantation. The distance 304 may be, for example, between approximately 450 to 2000 Å. In another instance, the distance 304 may be 0 μm or approximately 5 μm.

FIG. 9 is a perspective view of a second embodiment of a current confinement structure. In this particular embodiment, the current confinement layer 103 has cells 300 and, consequently, undoped regions 301 of two different sizes. For example, the larger cells 400 may be located under or proximate the p electrode and the smaller cells 401 may be located under or proximate the n electrode. This may prevent current crowding near the n electrode.

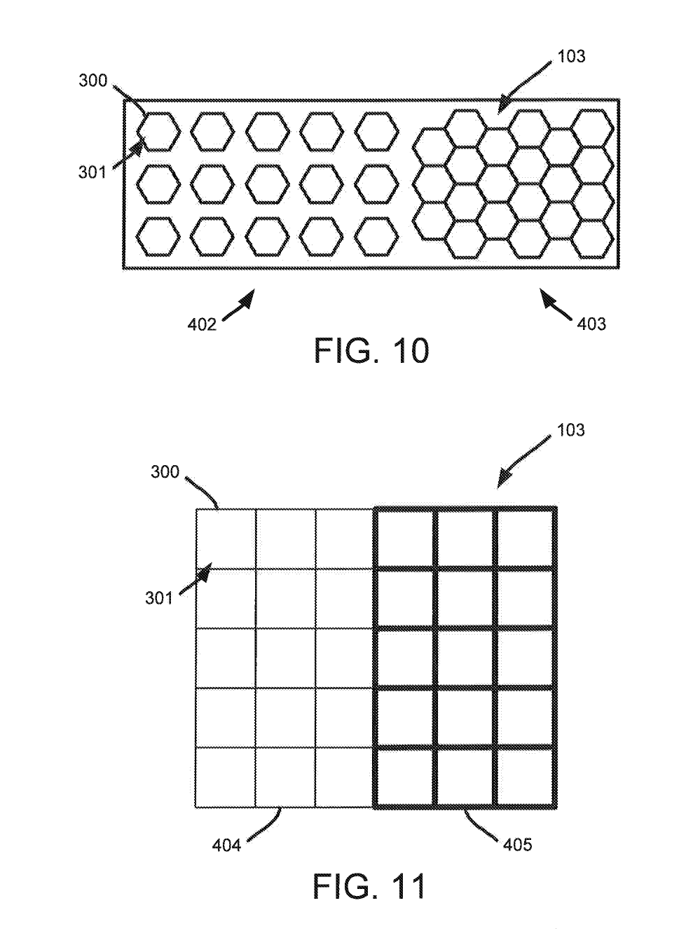

FIG. 10 is a top perspective view of a third embodiment of a current confinement structure. In this particular embodiment, the current confinement layer 103 has cells 300 that surround undoped regions 301. The cells 300 in FIG. 10 have different densities or have different distances between them. The cells 300 in area 402 are spaced farther apart or have a lower density than the cells 300 in area 403. Thus, the cells 300 in area 402 and the cells 300 in area 403 are spaced apart by different distances. For example, the area 402 may be located under or proximate the p electrode and the area 403 may be located under or proximate the n electrode. This may prevent current crowding near the n electrode.

FIG. 11 is a top perspective view of a fourth embodiment of a current confinement structure. In this particular embodiment, the current confinement layer 103 has cells 300 of different thicknesses that surround undoped regions 301. The cells 404 have thinner lines than the cells 405. For example, the cells 404 may be located under or proximate the p electrode and the cells 405 may be located under or proximate the n electrode. This may prevent current crowding near the n electrode.

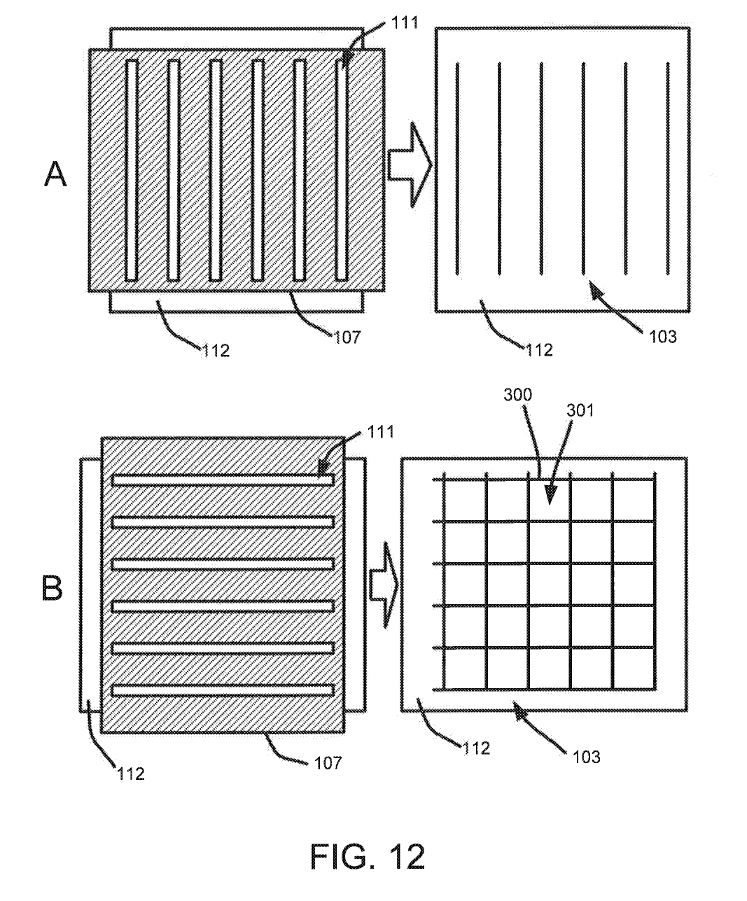

FIGS. 12A-B are perspective views of an embodiment forming a current confinement structure. On the left of FIG. 12A, a mask 107 with apertures 111 is disposed over a workpiece 112 on or from which an LED will be fabricated. This workpiece 112 may correspond to the n-type layer 102 or other layers or parts of the LED. The resulting implant pattern of the current confinement structure 103 using the mask 107 is illustrated on the right. On the left of FIG. 12B, the mask 107 and workpiece 112 are rotated 90° C. with respect to one another. If a second implant is performed with the mask 107 positioned as illustrated in FIG. 12B, the resulting implant pattern of the current confinement structure 103 is illustrated on the right. These two implants will form cells 300 that surround undoped regions 301. The various lines in the current confinement structure 103 may go beyond the various cells 300 to simplify alignment in one instance.

While specific n-type and p-type doping within an LED are listed in the embodiments herein, the current confinement structure can be applied to other regions than that illustrated. For example, the current confinement structure may be placed in a p-type GaN layer. In another example, the doped regions may be other materials than GaN.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of forming a workpiece comprising:
forming a first portion of a first layer;
performing a first patterned implant of said first layer with a species to form a current confinement structure in said first layer, wherein said current confinement structure defines a plurality of cells and each of said plurality of cells surrounds an undoped region; and
forming a second layer on said first layer, wherein said second layer has an opposite conductivity from said first layer.

2. The method of claim 1, wherein said first ayer and said second layer comprise GaN.

3. The method of claim 1, wherein said species is selected from the group consisting of H, N, He, Ar, O, Cr, Fe, Ne, F, Ti, C, Mg, and B.

4. The method of claim 1, further comprising forming a second portion of said first layer on said first portion after said first patterned implant and before said forming of said second layer.

5. The method of claim 1, further comprising performing a second patterned implant of said first layer with said species after performing said first patterned implant and before said forming of said second layer.

6. The method of claim 1, further comprising disposing a mask a distance away from said first layer prior to performing said first patterned implant.

7. The method of claim 1, further comprising forming a multiple quantum well between said first layer and said second layer.

8. The method of claim 1, further comprising etching a fraction of said second layer such that said first layer is exposed.

9. A light emitting diode comprising:
a first layer of material having a first conductivity;
a second layer of said material having a second conductivity opposite of said first conductivity;
a multiple quantum well disposed between said first layer and said second layer; and
a current confinement structure disposed in said first layer, wherein said current confinement structure defines a plurality of cells and each of said plurality of cells surrounds an undoped region.

10. The light emitting diode of claim 9, wherein said material is GaN and
wherein said first conductivity and said second conductivity are selected from the group consisting of p-type and n-type.

11. The light emitting diode of claim 9, wherein said first layer defines a first surface disposed on said multiple quantum well and an opposite second surface, and wherein said current confinement structure is disposed at a distance from said first surface between said first surface and said second surface.

12. The light emitting diode of claim 9, wherein said current confinement structure has a higher resistivity than said first layer.

13. The light emitting diode of claim 9, wherein said plurality of cells each consist of a square, a diamond, a rectangle, a circle, a triangle, and a polygon.

14. The light emitting diode of claim 9, wherein two of said undoped regions each have a different size.

15. A light emitting diode comprising:
an n-type GaN layer defining a first surface and an opposite second surface;
a p-type GaN layer;
a multiple quantum well disposed on said first surface of said n-type GaN layer and between said n-type GaN layer and said p-type GaN layer; and
a current confinement structure disposed a distance beneath said first surface of said n-type GaN layer, said current confinement structure defining a plurality of polygons, wherein each of said plurality of polygons surrounds an undoped region.

16. The light emitting diode of claim 15, wherein said current confinement structure has a higher resistivity than said n-type GaN layer.

17. The light emitting diode of claim 15, wherein one of said plurality of polygons and another of said plurality of polygons each have a different size.

18. The light emitting diode of claim 15, wherein said plurality of polygons comprise hexagons.

19. The light emitting diode of claim 15, wherein one of said plurality of polygons and another of said plurality of polygons each have a different thickness.

20. The light emitting diode of claim 15, wherein two of said plurality of polygons and another two of said plurality of polygons are each spaced apart a different distance.
